(19) United States
(12) Patent Application Publication
(10) Pub. No.: US 2022/0392519 A1
(43) Pub. Date: Dec. 8, 2022

(54) FULL DUPLEX DRAM FOR TIGHTLY COUPLED COMPUTE DIE AND MEMORY DIE

(71) Applicant: Intel Corporation, Santa Clara, CA (US)

(72) Inventors: Randy B. OSBORNE, Beaverton, OR (US); Christopher P. MOZAK, Portland, OR (US); Shankar Ganesh RAMASUBRAMANIAN, Hillsboro, OR (US)

(21) Appl. No.: 17/892,000

(22) Filed: Aug. 19, 2022

(51) Int. Cl. G11C 11/4093; H01L 25/065; G11C 11/4096; G11C 5/06

(52) U.S. Cl. CPC G11C 11/4093; H01L 25/0657; G11C 11/4096; G11C 5/063; G11C 5/066; H01L 2225/06544

(57) ABSTRACT

Methods and apparatus for opportunistic full duplex DRAM for tightly coupled compute die and memory die. A memory controller includes one or more memory channel input-output (IO) interfaces having sets of read data (RdDQ) lines and write data (WrDQ) lines, and includes logic to implement concurrent read and write operations utilizing the RdDQ lines and WrDQ lines. A memory channel IO interface may be coupled to one or more memory devices such as DRAM DIMMs or DRAM/SDRAM dies having a mating IO interface, such as using through-silicon vias (TSVs) and die-to-die interconnects. Circuitry in a memory device or die includes a macro block of IO drivers coupled to the memory channel IO circuitry via a macro interface supporting full duplex operations. IO drivers in a macro block may be connected to memory banks using half-duplex bi-direction links to different banks or full duplex links to the same bank.

### BACKGROUND INFORMATION

For the better part of three decades processor and memory performance generally scaled in accordance with Moore's law, where the fundamental performance improvements were obtained via increases in the number of transistors (enabled through decreases in feature size and larger dies) and increases in frequency. Eventually, Moore's law hit limitations relating to feature size and frequency. These limitations have been addressed on the processor side by adding more cores, on-chip or off-chip accelerators, Graphic Processor Units (GPUs) and various other approaches that increase the number and efficiency of compute elements. However, increasing memory performance has been more difficult, as there are practical limits to frequency and scaling the number of channels is limited when using conventional package technologies under which a processor or System on a Chip (SoC) with integrated memory controller(s) is coupled to memory devices (e.g., Dynamic Random Access Memory (DRAM) Dual Inline Memory Modules (DIMMs)) using wiring implemented in printed circuit boards coupled to pins or solder pads on the processor/SOC.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram illustrating selective elements in a memory subsystem including a memory controller coupled to a DIMM showing two ranks of DRAM devices;

FIG. 2 is a schematic diagram of a DRAM memory structure;

FIG. 3a shows a memory interface architecture that supports half duplex to macro and half duplex inside a macro, according to one embodiment;

FIG. 3b shows a memory interface architecture that supports full duplex to macro and half duplex inside a macro, according to one embodiment;

FIG. 3c shows a memory interface architecture that supports full duplex operations to a bank, according to one embodiment;

FIG. 3d shows a memory interface architecture that supports full duplex operations to bank groups, according to one embodiment;

FIG. 3e shows a memory interface architecture that supports full duplex operations to bank sets, according to one embodiment;

FIG. 4 is a schematic diagram of an example system including a memory controller coupled to one or more memory modules or memory devices in which the memory interface architectures of FIGS. 3a, 3b, 3c and 3d may be implemented;

FIG. 5 is a diagram illustrating an exemplary configuration of memory channels, a macro block of IO drivers, and groups of memory banks, according to one embodiment;

FIG. 5a is a diagram illustrating a variant of the configuration of FIG. 5 under which banks in Bank Groups are split into Bank Sets;

FIG. 5b is a diagram illustrating full duplex interfaces between the macro IO drivers block and each Bank Set;

FIG. 6 is a diagram illustrating an exemplary configuration under which banks are split into Bank Sets, with the macro block of IO drivers support a full duplex interface with each Bank Set, according to one embodiment;

FIG. 7 shows an exemplary timing diagram, according to one embodiment;

FIG. 8a shows an example of a PIM module;

FIG. 8b shows further details of the structure of a PIM module;

FIG. 8c shows another example of a PIM module including a CPU or XPU coupled to DRAMs in a stacked 3D structure;

FIG. 8d shows a variant of the PIM module of FIG. 8c where there are one or more layers of DRAM dies stacked above and below the CPU or XPU;

FIG. 9 is a chart showing the maximum bandwidth envelop for a memory system comprised with traditional half duplex channels with typical bank resources;

FIG. 10 is a chart showing the maximum bandwidth envelope for a memory system comprised of full duplex channels;

FIG. 11 is a chart showing the maximum bandwidth envelope for opportunistic full duplex; and

FIG. 12 is a block diagram of an exemplary system in which aspects of the embodiments disclosed herein may be implemented.

### DETAILED DESCRIPTION

Embodiments of methods and apparatus for opportunistic full duplex DRAM for tightly coupled compute die and memory die are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with aspects of the embodiments of memory interface architectures and associated apparatus described and illustrated herein, memory interface architectures are provided with sufficient wires and/or through silicon vias (TSVs) to support full duplex operation under which concurrent memory reads and memory writes are available. This provides opportunity for full duplex memory access operations when there are available channel resources, such as when there is good DRAM page locality. The full duplex capability also eliminates the performance penalty of read-write turnarounds of traditional half duplex interfaces for DRAM.

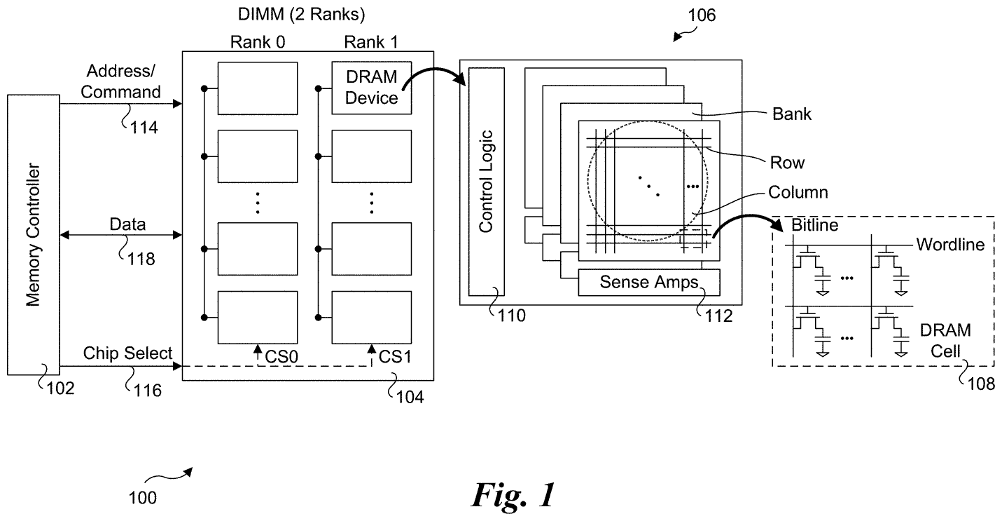

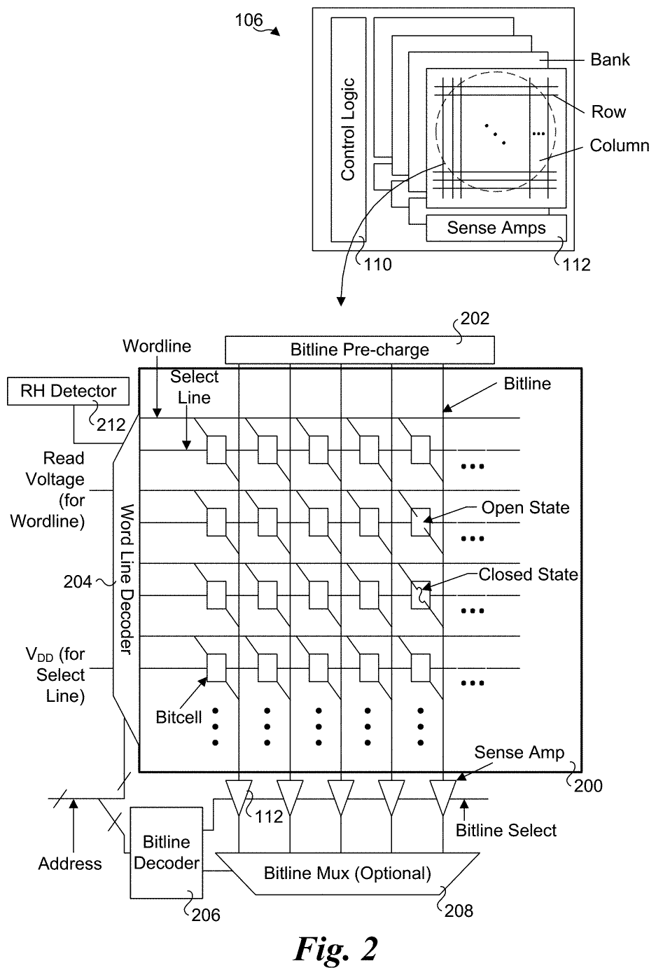

To better understand aspects of the teachings and principles of the embodiments disclosed herein, a brief primer on the operation of DRAM is provided with reference an exemplary memory subsystem illustrated in FIGS. 1 and 2. As shown in FIG. 1, selective elements of a memory subsystem 100 include a memory controller 102 coupled to a DIMM 104 showing two ranks of DRAM devices 106. Generally, a DRAM DIMM may have one or more ranks. Each DRAM device includes a plurality of banks comprising an array of DRAM cells 108 that are organized (laid out) and as rows and columns. Each row comprises a Wordline (or wordline), while each column comprises a Bitline (or bitline). Each DRAM device 106 further includes control logic 110 and sense amps 112 that are used to access DRAM cells 108.

As further shown in FIG. 1, memory controller provides inputs comprising address/commands 114 and chip select 116. For memory Writes, the memory controller inputs further include data 118 that are written to DRAM cells 108 based on the address and chip select inputs. Similarly, for memory Reads, data 118 stored in DRAM cells 108 identified by the address and chip select inputs is returned to memory controller 102.

As described herein, reference to memory devices (e.g., DRAM devices) can apply to different volatile memory types. Volatile memory is memory whose state (and therefore the data stored on it) is indeterminate if power is interrupted to the device. Dynamic volatile memory requires refreshing the data stored in the device to maintain state. One example of dynamic volatile memory includes DRAM, or some variant such as synchronous DRAM (SDRAM). A memory subsystem as described herein may be compatible with a number of memory technologies or standards, such as DDR3 (double data rate version 3, JESD79-3, originally published by JEDEC (Joint Electronic Device Engineering Council) on Jun. 27, 2007), DDR4 (DDR version 4, JESD79-4, originally published in September 2012 by JEDEC), LPDDR3 (low power DDR version 3, JESD209-3B, originally published in August 2013 by JEDEC), LPDDR4 (low power DDR version 4, JESD209-4, originally published by JEDEC in August 2014), WIO2 (Wide IO 2 (WideIO2), JESD229-2, originally published by JEDEC in August 2014), HBM (high bandwidth memory DRAM, JESD235, originally published by JEDEC in October 2013), LPDDR5 (originally published by JEDEC in February 2019), HBM2 ((HBM version 2), originally published by JEDEC in December 2018), DDR5 (DDR version 5, originally published by JEDEC in July 2020), or others or combinations of memory technologies, and technologies based on derivatives or extensions of such specifications.

Under conventional (S)DRAM memory, data are generally accessed (Read and Written) using cachelines (also called cache lines) comprising a sequence of memory cells (bits) in a wordline. The cachelines for a given memory architecture generally have a predetermined width or size, such as 64 Bytes, noting other widths/sizes maybe used.

Referring to FIG. 2, the DRAM device 106 structure includes a bank 200 including an array of memory cells called bitcells organized as wordlines and bitlines. A bitcell may have an open state or closed state (or otherwise have a capacitor that is charged or uncharged). A bitline pre-charge 202 and a word inline decoder 204 are coupled to bank 200. A bitline decoder 206 is used for selecting bitlines. An optional bitline mux (multiplexer) 208 may be used to multiplex the outputs of sense amps 112.

To change the logic level for a cell, the cell's transistor is used to charge or discharge the capacitor. A charged capacitor represents a logic high, or ‘1’, while a discharged capacitor represents a logic low, or ‘0’. The charging/discharging is done via the wordline and bitline. During a read or write, the wordline goes high and the transistor connects the capacitor to the bitline. Whatever value is on the bitline (‘1’ or ‘0’) gets stored or retrieved from the capacitor. Thus, to access data in a given row, the wordline for the row is activated (this is also referred to as row activation).

Generally, the charge stored on each capacitor is too small to be read directly and is instead measured by a sense amplifier (e.g., sense amps 112). The sense amplifier detects the minute differences in charge and outputs the corresponding logic level. The act of reading from the bitline forces the charge to flow out of the capacitor. Thus, in DRAM, Reads are destructive. To get around this, an operation known as precharging is done to put the value read from the bitline back into the capacitor.

Equally problematic is the fact that the capacitors leak charge over time. Therefore, to maintain the data stored in memory the capacitors must be refreshed periodically. Refreshing works just like a read and ensures data is never lost. This is where DRAM gets the “Dynamic” moniker from—the charge on a DRAM cell is dynamically refreshed every so often (e.g., every 64 ms).

As used herein, multiple memory controller channels are grouped into “macros.” In one embodiment, a macro has four channels with 32 GB/s bandwidth in each direction (i.e., 32 GB/s read and 32 GB/s write bandwidth). The macro has 16 banks per channel for a total of 64 banks per macro. Other combinations of channels and banks may also be used.

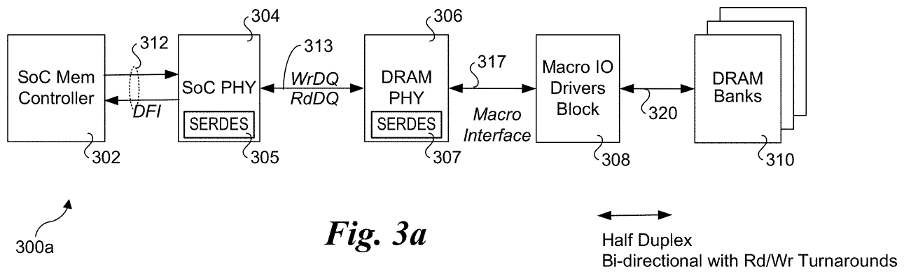

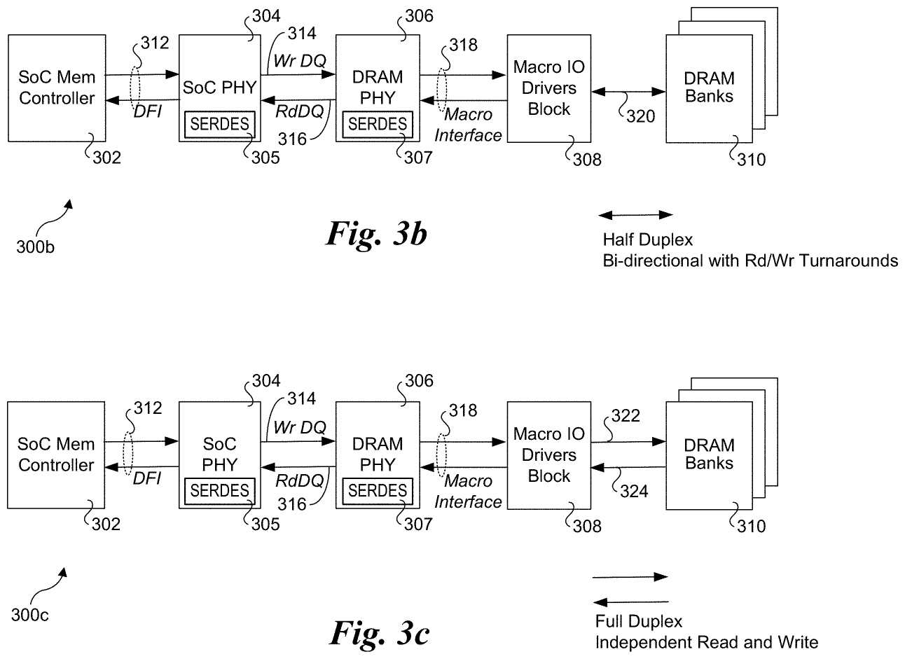

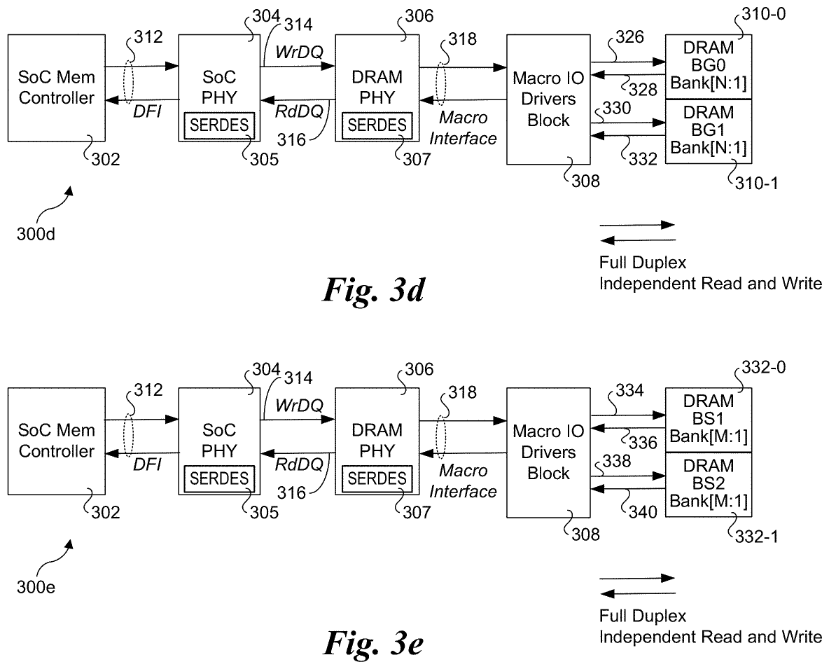

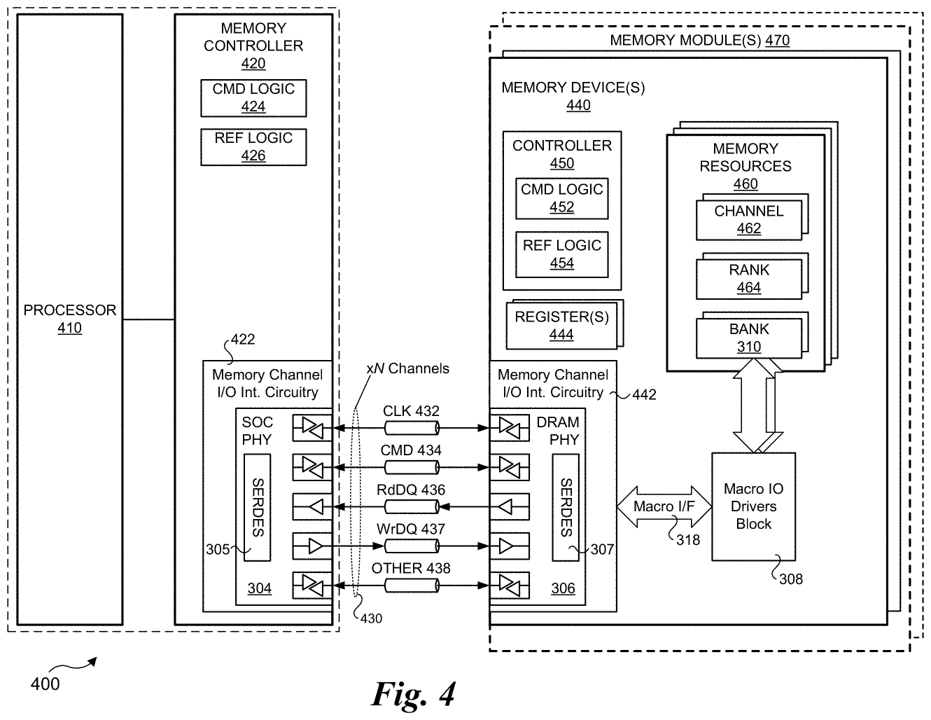

FIG. 3a shows a memory interface architecture 300a illustrating a current architecture that supports half duplex to macro and half duplex inside a macro. The block-level components include a System on a Chip (SoC) memory controller 302, an SoC Physical Layer (PHY) 304, a DRAM PHY 306, a macro input-output (IO) drivers block 308, and an array of DRAM banks 310. A DDR PHY Interface (DFI) protocol 312 is used between SoC memory controller 302 and SoC PHY 304. DFI defines signals, timing, and programmable parameters required to transfer control information and data to and from the DRAM devices, and between the memory controller and the PHY on the SoC.

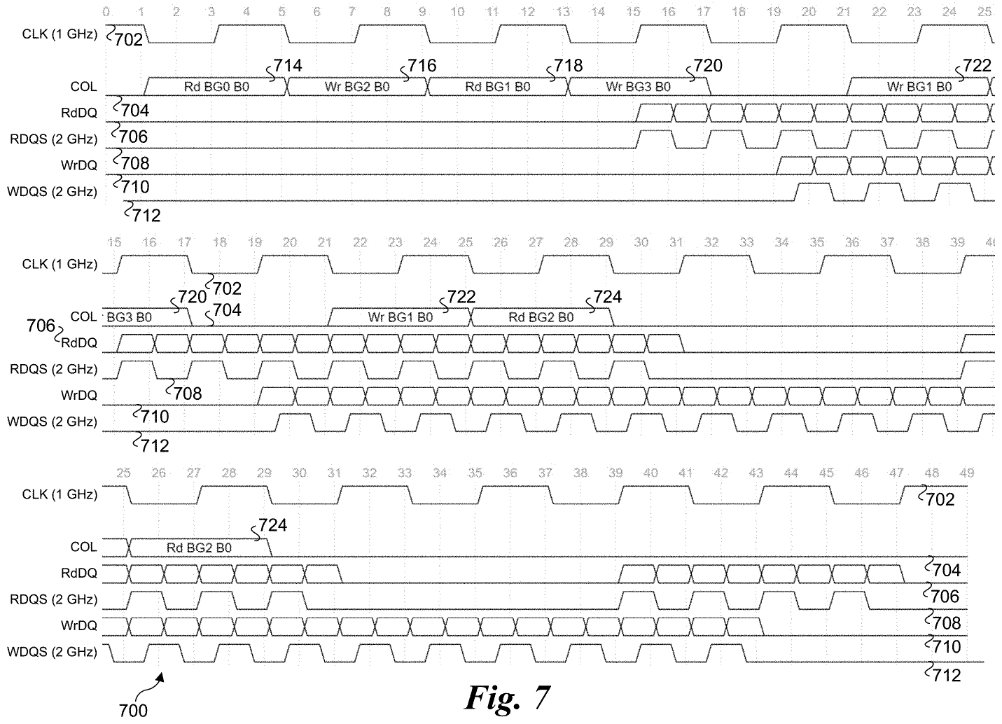

For illustrative purposes and simplicity, the signals shown between SoC PHY 304 and DRAM PHY 306 are depicted as bi-direction lines 313 that are used for Write data (DQ) (WrDQ) signals and Read data (RdDQ) signals. The Write and Read data sent over bi-direction lines 313 are serialized at the sending end, sent over the lines as differential serial signals, and then deserialized at the receiving end using SERDES blocks 305 and 307 in SoC PHY 304 and DRAM PHY 306. As described and illustrated below in FIG. 7, there will also be control signals, clock signals, and other signals used to facilitate transfer of Write and Read data to and from a memory device.

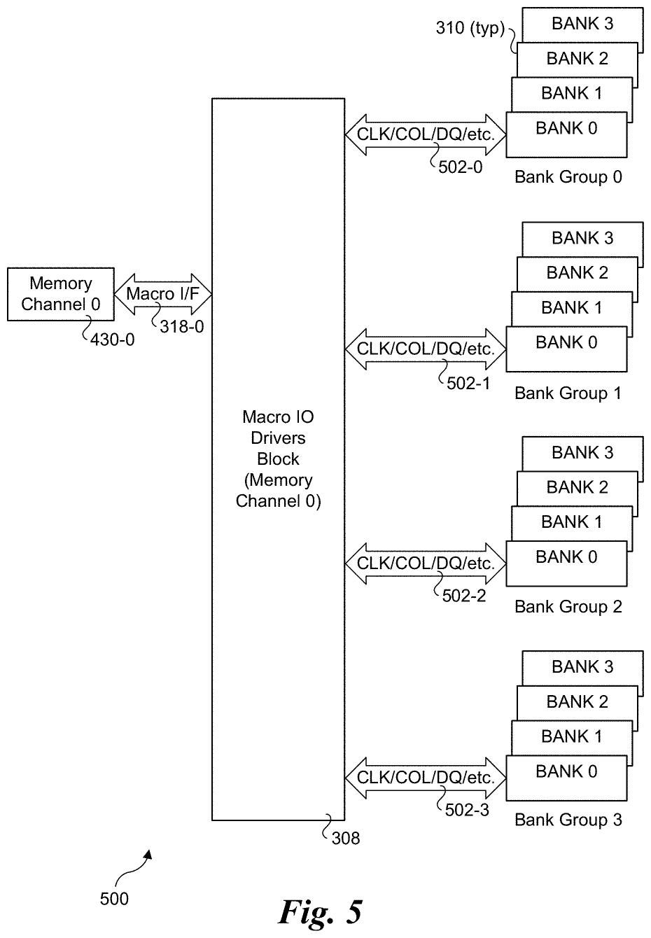

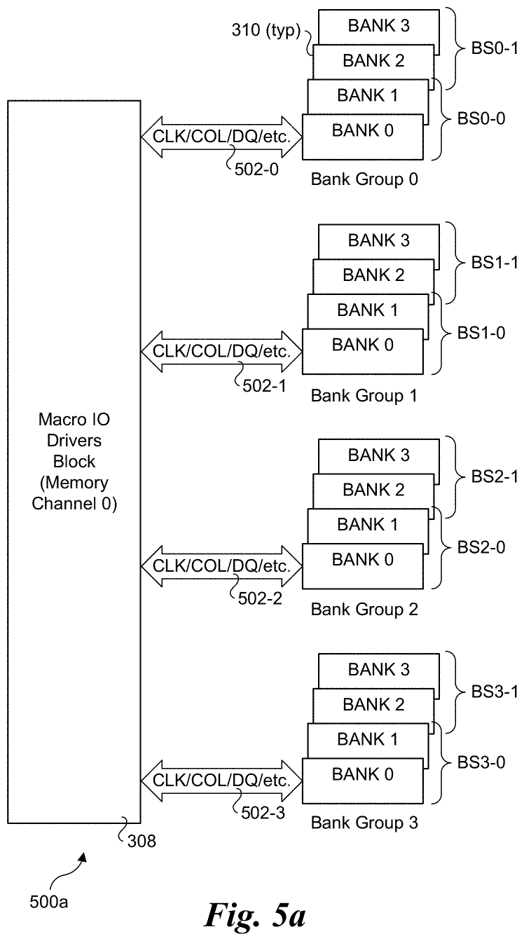

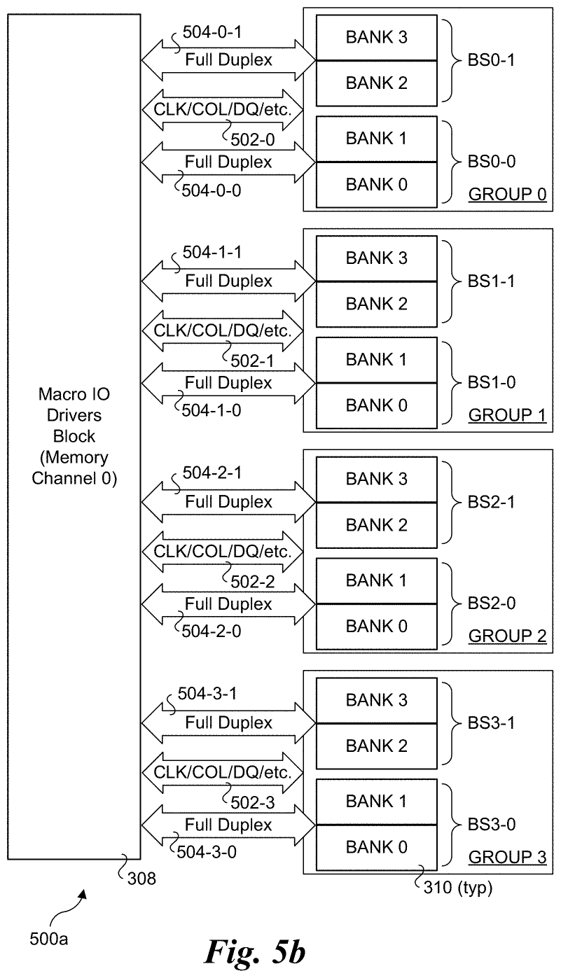

A half-duplex macro interface 317 is used for communication between DRAM PHY 306 and Macro IO drivers block 308. IO drivers in Macro IO drivers block 308 employ a half-duplex bi-directional interface 320 with each of multiple DRAM banks, as depicted by a single DRAM bank 310 for illustrative purposes; it will be understood that a given Macro IO drivers block may include IO drivers for multiple DRAM banks, such as shown in FIG. 5 and described below. Bi-directional interface 320 supports sequential (non-concurrent) memory reads and writes with Read/Write (Rd/Wr) turnarounds. Generally, a Write to Read (W2R) turnaround is limited by the tW2R, which is the latency of PHY→Bank Sense Amp→PHY signal path. The Read to Write (R2W) turnaround is limited by the contention/protocol on the shared TSV interconnects. Both turnarounds are rounded to the nearest tCK.

FIG. 3b shows a memory interface architecture 300b illustrating a first embodiment that supports full duplex to macro and half duplex inside a macro. The primary differences between the conventional approach in FIG. 3a are that the bi-directional RdDQ/WrDQ interface 313 is replaced with a full duplex interface including separate WrDQ lines 314 and RdDQ lines 316, and half-duplex macro interface 317 is replaced with full duplex macro interface 318.

FIG. 3c shows a memory interface architecture 300c that supports full duplex operations to a bank. As shown by like-numbered blocks, interfaces, and signals, the configurations of memory interface architectures 300b and 300c are similar up to macro IO drivers block 308. As shown, in this embodiment a set of IO drivers in macro IO drivers block 308 is connected to an array of DRAM banks 310 to facilitate full duplex operations via an interface including unidirectional bank write signals 322 and bank read signals 324 that support independent and concurrent read and write operations.

FIG. 3d shows a memory interface architecture 300d that supports full duplex operations to bank groups. Bank groups are an existing industry DRAM feature in which banks are organized into groups to mitigate the impact of external DRAM bandwidth scaling faster than DRAM core timings. Within a bank group the CAS to CAS timings (and other timings) are dictated by the DRAM core timings, and the CAS to CAS timings are larger (e.g. 2×) the CAS to CAS timing to support full bandwidth on the external interface. Between bank groups the CAS to CAS timings are limited by the external interface, rather than the internal DRAM timings.

The like-numbered blocks, interfaces, and signals in FIG. 3d show the configurations of memory interface architectures 300b and 300c are similar up to macro IO drivers block 308. Under memory interface architecture 300d, a set of IO drivers in macro IO drivers block 308 is connected to DRAM bank groups 310-0 and 310-1 via respective pairs of unidirectional bank write signals and bank read signals to each bank in a bank group, as depicted by a bank write signal 326 and a bank read signal 328 for DRAM bank 310-0 and a bank write signal 330 and a bank read signal 332 for DRAM bank 310-1. Under the illustrated embodiment, there is a pair of write and read signals for each of multiple bank groups. For simplicity, only two bank groups are shown in FIGS. 3d and 3e (below); however, it will be understood that there may be two or more bank groups.

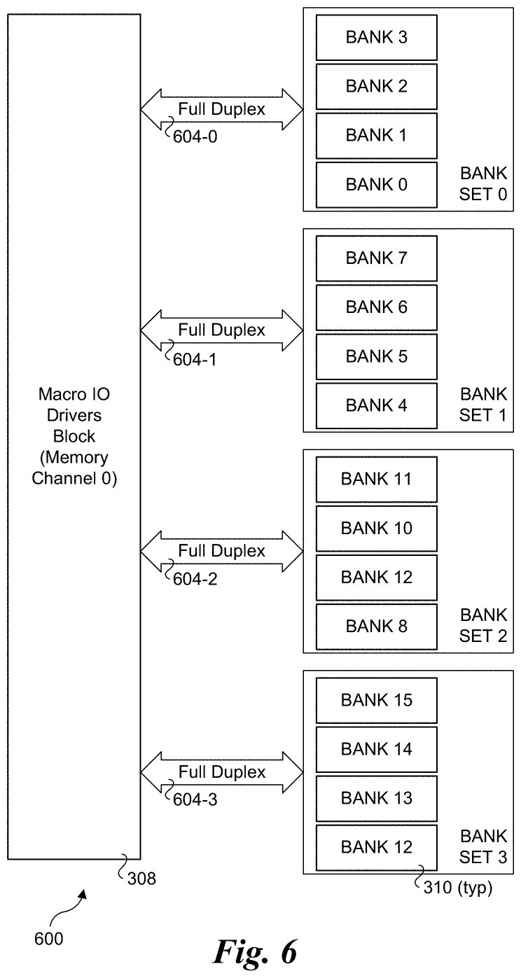

According to an aspect of some embodiments, full duplex operations to bank sets are supported. A bank set is a subset of the banks that connect to a full duplex interface; various memory device bank set configurations are described and illustrated below. Generally, a bank set does not have to align with a bank group: the full duplex data paths are orthogonal to the bank organization and banks timings. In some embodiments, the banks in a bank group are split into bank sets (e.g., as in FIG. 5b). In other embodiments, the banks in a bank set are split into bank groups. In yet other embodiments, the banks on a memory device are split into multiple bank sets without using bank groups (e.g., as in FIG. 6). More generally, bank sets may be aligned with bank groups in some embodiments, and not aligned with bank groups in other embodiments.

FIG. 3e shows a memory interface architecture 300e that supports full duplex operations to bank sets. As before, the configurations of memory interface architectures 300b and 300e are similar up to macro IO drivers block 308. Under memory interface architecture 300e, a set of IO drivers in macro IO drivers block 308 is connected to DRAM banks 332-0 and 332-1 via respective pairs of unidirectional bank write signals and bank read signals to each bank in the bank set, as depicted by a bank write signal 334 and a bank read signal 336 for DRAM bank 330-0 and a bank write signal 338 and a bank read signal 340 for DRAM bank 332-1. Under the illustrated embodiment, there is a pair of write and read signals for each of two or more bank sets.

FIG. 4 illustrates an example system 400. In some examples, as shown in FIG. 4, system 400 includes a processor and elements of a memory subsystem in a computing device. Processor 410 represents a processing unit of a computing system that may execute an operating system (OS) and applications, which can collectively be referred to as the host or the user of the memory subsystem. The OS and applications execute operations that result in memory accesses. Processor 410 can include one or more separate processors. Each separate processor may include a single processing unit, a multicore processing unit, or a combination. The processing unit may be a primary processor such as a central processing unit (CPU), a peripheral processor such as a graphics processing unit (GPU), or a combination. Memory accesses may also be initiated by devices such as a network controller or hard disk controller (not separately shown). Such devices may be integrated with the processor in some systems or attached to the processer via a bus (e.g., a PCI express bus), or a combination. System 400 may be implemented as an SoC or may be implemented with standalone components.

Descriptions referring to a “DRAM”, “SDRAM, “DRAM device” or “SDRAM device” may refer to a volatile random access memory device. The memory device, SDRAM or DRAM may refer to the die itself, to a packaged memory product that includes one or more dies, or both. In some examples, a system with volatile memory that needs to be refreshed may also include at least some nonvolatile memory.

Memory controller 420, as shown in FIG. 4, may represent one or more memory controller circuits or devices for system 400. Also, memory controller 420 may include logic and/or features that generate memory access commands in response to the execution of operations by processor 410. In some examples, memory controller 420 may access one or more memory device(s) 440. For these examples, memory device(s) 440 may be SDRAM or DRAM devices in accordance with any referred to above. Memory device(s) 440 may be organized and managed through different channels, where these channels may couple in parallel to multiple memory devices via buses and signal lines. Each channel may be independently operable. Thus, separate channels may be independently accessed and controlled, and the timing, data transfer, command and address exchanges, and other operations may be separate for each channel. Coupling may refer to an electrical coupling, communicative coupling, physical coupling, or a combination of these. Physical coupling may include direct contact. Electrical coupling, for example, includes an interface or interconnection that allows electrical flow between components, or allows signaling between components, or both. Communicative coupling, for example, includes connections, including wired or wireless, that enable components to exchange data.

According to some examples, settings for each channel are controlled by separate mode registers or other register settings. For these examples, memory controller 420 may manage a separate memory channel, although system 400 may be configured to have multiple channels managed by a single memory controller, or to have multiple memory controllers on a single channel. In one example, memory controller 420 is part of processor 410, such as logic and/or features of memory controller 420 are implemented on the same die or implemented in the same package space as processor 410, sometimes referred to as an integrated memory controller or IMC.

Memory controller 420 includes IO interface circuitry 422 to couple to a memory bus, such as a memory channel as referred to above. In FIG. 4, a single channel 430 is illustrated; a memory controller may include one or more such channels as depicted by xN channels, where N is one or more. IO interface circuitry 422 (as well as IO interface circuitry 442 of memory device(s) 440) may include pins, pads, connectors, signal lines, traces, or wires, or other hardware to connect the devices, or a combination of these. IO interface circuitry 422 may include a hardware interface. As shown in FIG. 4, IO interface circuitry 422 includes at least drivers/transceivers for signal lines. Commonly, wires within an integrated circuit interface couple with a pad, pin, or connector to interface signal lines or traces or other wires between devices. IO interface circuitry 422 can include drivers, receivers, transceivers, or termination, or other circuitry or combinations of circuitry to exchange signals on the signal lines between memory controller 420 and memory device(s) 440. The exchange of signals includes transmit and receive signals. While shown as coupling IO interface circuitry 422 from memory controller 420 to IO interface circuitry 442 of memory device(s) 440, it will be understood that in an implementation of system 400 where groups of memory device(s) 440 are accessed in parallel, multiple memory devices can include IO interface circuitry to the same interface of memory controller 420. In an implementation of system 400 including one or more memory module(s) 470, IO interface circuitry 442 may include interface hardware of memory module(s) 470 in addition to interface hardware for memory device(s) 440. Other memory controllers 420 may include multiple, separate interfaces to one or more memory devices of memory device(s) 440.

In some examples, memory controller 420 may be coupled with memory device(s) 440 via multiple signal lines. The multiple signal lines may include at least a clock (CLK) 432, a command/address (CMD) 434, read data lines (RdDQ) 436 and write data lines (WrDQ) 437, and zero or more other signal lines 438. According to some examples, a composition of signal lines coupling memory controller 420 to memory device(s) 440 may be referred to collectively as a memory bus. The signal lines for CMD 434 may be referred to as a “command bus”, a “C/A bus” or an ADD/CMD bus, or some other designation indicating the transfer of commands. The signal lines for RdDQ 436 and WrDQ 437 may be referred to as a “data bus”.

According to some examples, independent channels may have different clock signals, command buses, data buses, and other signal lines. For these examples, system 400 may be considered to have multiple “buses,” in the sense that an independent interface path may be considered a separate bus. It will be understood that in addition to the signal lines shown in FIG. 4, a bus may also include at least one of strobe signaling lines, alert lines, auxiliary lines, or other signal lines, or a combination of these additional signal lines. It will also be understood that serial bus technologies can be used for transmitting signals between memory controller 420 and memory device(s) 440. An example of a serial bus technology is 8B10B encoding and transmission of high-speed data with embedded clock over a single differential pair of signals in each direction. In some examples, CMD 434 represents signal lines shared in parallel with multiple memory device(s) 440. In other examples, multiple memory devices share encoding command signal lines of CMD 434, and each has a separate chip select (CS_n) signal line to select individual memory device(s) 440.

In some examples, the bus between memory controller 420 and memory device(s) 440 includes a subsidiary command bus routed via signal lines included in CMD 434 and a subsidiary data bus to carry the write and read data routed via signal lines included in RdDQ 436 and WrDQ 437. In some examples, CMD 434 and DQ 436 may separately include bidirectional lines.

According to some examples, in accordance with a chosen memory technology and system design, signals lines included in other 438 may augment a memory bus or subsidiary bus. For example, strobe line signal lines for a DQS. Based on a design of system 400, or memory technology implementation, a memory bus may have more or less bandwidth per memory device included in memory device(s) 440. The memory bus may support memory devices included in memory device(s) 440 that have either an x64 interface, and x32 interface, a x16 interface, a x8 interface, or other interface. The convention “xW,” where W is an integer that refers to an interface size or width of the interface of memory device(s) 440, which represents a number of signal lines to exchange data with memory controller 420. The interface size of these memory devices may be a controlling factor on how many memory devices may be used concurrently per channel in system 400 or coupled in parallel to the same signal lines. In some examples, high bandwidth memory devices, wide interface memory devices, or stacked memory devices, or combinations, may enable wider interfaces, such as a x128 interface, a x256 interface, a x512 interface, a x1024 interface, or other data bus interface width.

According to some examples, memory device(s) 440 represent memory resources for system 400. For these examples, each memory device included in memory device(s) 440 is a separate memory die. Separate memory devices may interface with multiple (e.g., 2) channels per device or die. A given memory device of memory device(s) 440 may include IO interface circuitry 442 and may have a bandwidth determined by an interface width associated with an implementation or configuration of the given memory device (e.g., x32, x16 or x8 or some other interface bandwidth). IO interface circuitry 442 may enable the memory devices to interface with memory controller 420. IO interface circuitry 442 may include a hardware interface and operate in coordination with IO interface circuitry 422 of memory controller 420. As depicted in FIG. 4, IO interface circuitry 442 is associated with DRAM PHY 304 and includes SERDES 307.

In some examples, multiple memory device(s) 440 may be connected in parallel to the same command and data buses (e.g., via CMD 434 and RdDQ 436 and WrDQ 427). In other examples, multiple memory device(s) 440 may be connected in parallel to the same command bus but connected to different data buses. For example, system 400 may be configured with multiple memory device(s) 440 coupled in parallel, with each memory device responding to a command, and accessing memory resources 460 internal to each memory device. For a write operation, an individual memory device of memory device(s) 440 may write a portion of the overall data word, and for a read operation, the individual memory device may fetch a portion of the overall data word. As non-limiting examples, a specific memory device may provide or receive, respectively, 8 bits of a 128-bit data word for a read or write operation, or 8 bits or 16 bits (depending for a x8 or a x16 device) of a 256-bit data word. The remaining bits of the word may be provided or received by other memory devices in parallel.

According to some examples, memory device(s) 440 may be disposed directly on a motherboard or host system platform (e.g., a PCB (printed circuit board) on which processor 410 is disposed) of a computing device. As described an illustrated below in FIGS. 7a and 7b, memory device(s) 440 and memory controller 420 may be implemented in a 3d stacked structure. Alternatively, memory controller 420 may be implemented in a die of an SoC that is coupled to one or more memory dies (comprising memory device(s) 440) via die-to-die interconnects.

Memory device(s) 440 may be organized into memory module(s) 470. In some examples, memory module(s) 470 may represent dual inline memory modules (DIMMs). In some examples, memory module(s) 470 may represent other organizations or configurations of multiple memory devices that share at least a portion of access or control circuitry, which can be a separate circuit, a separate device, or a separate board from the host system platform. In some examples, memory module(s) 470 may include multiple memory device(s) 440, and memory module(s) 470 may include support for multiple separate channels to the included memory device(s) 440 disposed on them.

In some examples, memory device(s) 440 may be incorporated into a same package as memory controller 420. For example, incorporated in a multi-chip-module (MCM), a package-on-package with through-silicon via (TSV), or other techniques or combinations. Similarly, in some examples, memory device(s) 440 may be incorporated into memory module(s) 470, which themselves may be incorporated into the same package as memory controller 420. It will be appreciated that for these and other examples, memory controller 420 may be part of or integrated with processor 410.

As shown in FIG. 4, in some examples, memory device(s) 440 include memory resources 460. Memory resources 460 may represent individual arrays of memory locations or storage locations for data. Memory resources 460 may be managed as rows of data, accessed via wordline (rows) and bitline (individual bits within a row) control. Memory resources 460 may be organized as separate channels 462, ranks 464, and banks 310 of memory. Channels may refer to independent control paths to storage locations within memory device(s) 440. Ranks may refer to common locations across multiple memory devices (e.g., same row addresses within different memory devices). Banks may refer to arrays of memory locations within a given memory device of memory device(s) 440. Banks may be divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to access memory resources 460. For example, the same physical memory locations can be accessed over a specific channel as a specific bank, which can also belong to a rank. Thus, the organization of memory resources 460 may be understood in an inclusive, rather than exclusive, manner.

For a given channel, IO interface circuitry 442 is coupled to a given macro block 308 of IO drivers via a macro interface 318. In turn, IO drivers in a macro block 308 may be coupled to banks 310 using bi-directional half-duplex links such as illustrated in FIGS. 3a and 3b above or links supporting full duplex operations, such as illustrated in FIG. 3c.

According to some examples, as shown in FIG. 4, memory device(s) 440 include one or more register(s) 444. Register(s) 444 may represent one or more storage devices or storage locations that provide configuration or settings for operation memory device(s) 440. In one example, register(s) 444 may provide a storage location for memory device(s) 440 to store data for access by memory controller 420 as part of a control or management operation. For example, register(s) 444 may include one or more mode registers and/or may include one or more multipurpose registers.

In some examples, writing to or programming one or more registers of register(s) 444 may configure memory device(s) 440 to operate in different “modes”. For these examples, command information written to or programmed to the one or more register may trigger different modes within memory device(s) 440. Additionally, or in the alternative, different modes can also trigger different operations from address information or other signal lines depending on the triggered mode. Programmed settings of register(s) 444 may indicate or trigger configuration of IO settings. For example, configuration of timing, termination, on-die termination (ODT), driver configuration, or other IO settings.

In some examples, as shown in FIG. 4, memory device(s) 440 includes controller 450. Controller 450 may represent control logic within memory device(s) 440 to control internal operations within memory device(s) 440. For example, controller 450 decodes commands sent by memory controller 420 and generates internal operations to execute or satisfy the commands. Controller 450 may be referred to as an internal controller and is separate from memory controller 420 of the host. Controller 450 may include logic and/or features to determine what mode is selected based on programmed or default settings indicated in register(s) 444 and configure the internal execution of operations for access to memory resources 460 or other operations based on the selected mode. Controller 450 generates control signals to control the routing of bits within memory device(s) 440 to provide a proper interface for the selected mode and direct a command to the proper memory locations or addresses of memory resources 460. Controller 450 includes command (CMD) logic 452, which can decode command encoding received on command and address signal lines. Thus, CMD logic 452 can be or include a command decoder. With command logic 452, memory device can identify commands and generate internal operations to execute requested commands.

Referring again to memory controller 420, memory controller 420 includes CMD logic 424, which represents logic and/or features to generate commands to send to memory device(s) 440. The generation of the commands can refer to the command prior to scheduling, or the preparation of queued commands ready to be sent. Generally, the signaling in memory subsystems includes address information within or accompanying the command to indicate or select one or more memory locations where memory device(s) 440 should execute the command. In response to scheduling of transactions for memory device(s) 440, memory controller 420 can issue commands via IO interface circuitry 422 to cause memory device(s) 440 to execute the commands. In some examples, controller 450 of memory device(s) 440 receives and decodes command and address information received via IO interface circuitry 442 from memory controller 420. Based on the received command and address information, controller 450 may control the timing of operations of the logic, features and/or circuitry within memory device(s) 440 to execute the commands. Controller 450 may be arranged to operate in compliance with standards or specifications such as timing and signaling requirements for memory device(s) 440. Memory controller 420 may implement compliance with standards or specifications by access scheduling and control.

In some examples, memory controller 420 includes refresh (REF) logic 426. REF logic 426 may be used for memory resources that are volatile and need to be refreshed to retain a deterministic state. REF logic 426, for example, may indicate a location for refresh, and a type of refresh to perform. REF logic 426 may trigger self-refresh within memory device(s) 440 or execute external refreshes which can be referred to as auto refresh commands by sending refresh commands, or a combination. According to some examples, system 400 supports all bank refreshes as well as per bank refreshes. All bank refreshes cause the refreshing of banks within all memory device(s) 440 coupled in parallel. Per bank refreshes cause the refreshing of a specified bank within a specified memory device of memory device(s) 440. In some examples, controller 450 within memory device(s) 440 includes a REF logic 454 to apply refresh within memory device(s) 440. REF logic 454, for example, may generate internal operations to perform refresh in accordance with an external refresh received from memory controller 420. REF logic 454 may determine if a refresh is directed to memory device(s) 440 and determine what memory resources 460 to refresh in response to the command.

FIG. 5 shows an exemplary configuration 500 of a memory channel, a macro block, and groups of memory banks. This diagram shows a single memory channel 430-0, which is also labeled memory channel 0; similar circuitry would be replicated for each of multiple memory channels when multiple memory channels are supported. Memory channel 430-0 is connected to a macro IO drivers block 308 via a macro interface 318-0. Macro IO drivers block 308 provides IO signals to groups of memory banks 310, as depicted by Bank Groups 0, 1, 2, and 3, and signals 502-0, 502-1, 502-2, and 502-3. It will be recognized by those skilled in the art that some signals may be provided to each bank in a bank group as a common signal (such as clock signals), while other signals are provided to individual banks in a bank group.

Under configuration 500 there is a single memory channel coupled to one Macro block of IO drivers, which is coupled to four Bank Groups, each having 4 banks. However, this is merely an exemplary configuration and non-limiting, as other configurations may be used as well. For example, a respective macro block of IO drivers could be coupled to a respective memory channel via a macro interface, or two memory channels may be coupled to the same macro block of IO drivers. The number of banks in a bank group and number of bank groups coupled to a macro block of IO drivers may also vary.

FIGS. 5a and 5b shows a configuration 500a under which the banks in each of Bank Groups 0, 1, 2, and 3 are split it a pair of bank sets. The banks in Bank Group 0 are split into bank sets BS0-0 and BS0-1, the banks in Bank Group 1 are split into bank sets BS1-0 and BS1-1, the banks in Bank Group 2 are split into bank sets BS2-0 and BS2-1, and the banks in Bank Group 3 are split into bank sets BS3-0 and BS3-1. As shown in FIG. 5b, there is set of IO drivers in Macro IO drivers block 308 supping a full duplex interface with each of these bank sets, as depicted by full duplex interfaces 504-0-0, 504-0-1, 504-1-0, 504-1-1, 504-2-0, 504-2-1, 504-3-0, and 504-3-1. Each of these full duplex interfaces may be operated independently from the others. As shown in FIGS. 5a and 5b, Macro IO drivers block 308 also provides IO signals 502-0, 502-1, 502-2, and 502-3 to respective Bank Groups 0, 1, 2, and 3.

FIG. 6 shows a configuration 600 under which full duplex interfaces are provided to four Bank Sets 0, 1, 2, and 3 without employing Bank Groups. Each Bank Set includes four banks, and the full duplex interfaces include full duplex interface 604-0 for Bank Set 0, full duplex interface 604-1 for Bank Set 1, full duplex interface 604-2 for Bank Set 2, and full duplex interface 604-3 for Bank Set 3.

FIG. 7 shows a timing diagram for the case of banks sets matching bank groups. The timing diagram 700 illustrates selective signals including a clock (CLK) signal 702, a column select (COL) signal 704, an RdDQ differential signal 706, a Read data strobe (RDQS) 708, an WrDQ differential signal 710, and a Write data strobe (WDQS) 712. The diagram assumes:

tCCD_RD_S=tCCD_WR_S=2 nS

tWTR_S=tRTW S=0 nS

tWTR_L=(BL+3 nS) and tRTW_L=(BL+1 nS)

Read/Write CAS Commands are serialized on a 2× Column bus. Could also have separate buses.

Separate (RdDQ, RDQS) vs. (WrDQ, WDQS) buses with parallel, simultaneous operation,

where tCCD_RD_S is read CAS in one bank group to a read CAS in another bank group, tCCD_WR_S is write CAS in one bank group to a write CAS in another bank group, tWTR_S is write CAS in one bank group to a read CAS in another bank group, tRTW_S is read CAS in one bank group to a write CAS in another bank group, tWTR_L is write CAS in one bank group to a read CAS in the same bank group, tRTW_L is write CAS in one bank group to a read CAS in the same bank group, and BL is the data burst length in command clocks.

COL signal 704 is connected to multiple memory bank groups and banks within bank groups, such as illustrated in FIGS. 5, 5a, and 5b and described above. COL signal 704 is used to select columns for (in sequence) a Read of bank 0 from bank group 0 (Rd BG0 B0 714), a Write to bank 0 in bank group 2 (Wr BG2 B0 716), a Read of bank 0 from bank group 1 (Rd BG1 B0 718), a Write to bank 0 in bank group 3 (Wr BG3 B0 720), a Write to bank 0 in bank group 1 (Wr BG1 B0 722), and a Read of bank 0 from bank group 2 (Rd BG2 B0 724).

As shown at a CLK time 15, the Read data strobe (RDQS 708) is activated to begin reading data (depicted by RdDQ 706) from bank 0 in each of bank group 0 and bank group 1. At CLK time 19, Write data begins to be written in parallel (concurrently with read data operations) to bank 0 of bank group 2 and bank group 3, as depicted by activation of WrDQ 710 and WDQS 712. As further illustrated, the Read data strobe RDQS 708 is in phase relative to RdDQ 706, while the Write data strobe (WDQS 712) is 50% out of phase relative to WrDQ 710 in accordance with applicable JEDEC standards for the memory type and memory interfaces being used that employ these Read and Write phase offsets. Subsequently, in cooperation with WR BG1 B0 722 and Rd BG2 B0 724, data are written to bank 0 of bank group 1 and read from bank 0 of bank group 2.

Generally, the principles and teachings disclosed herein may be applied to various packages and configurations, including stacked die structures and packages, such as processor-in-memory (PIM) modules. (PIM modules may also be called compute on memory modules or compute near memory modules.) PIMs may be used for various purposes but are particularly well-suited for memory-intensive workload such as but not limited to performing matrix mathematics and accumulation operations. In a PIM module (which are sometimes called PIM chips when the stacked die structures are integrated on the same chip), the processor or CPU and stacked memory structures are combined in the same chip or package.

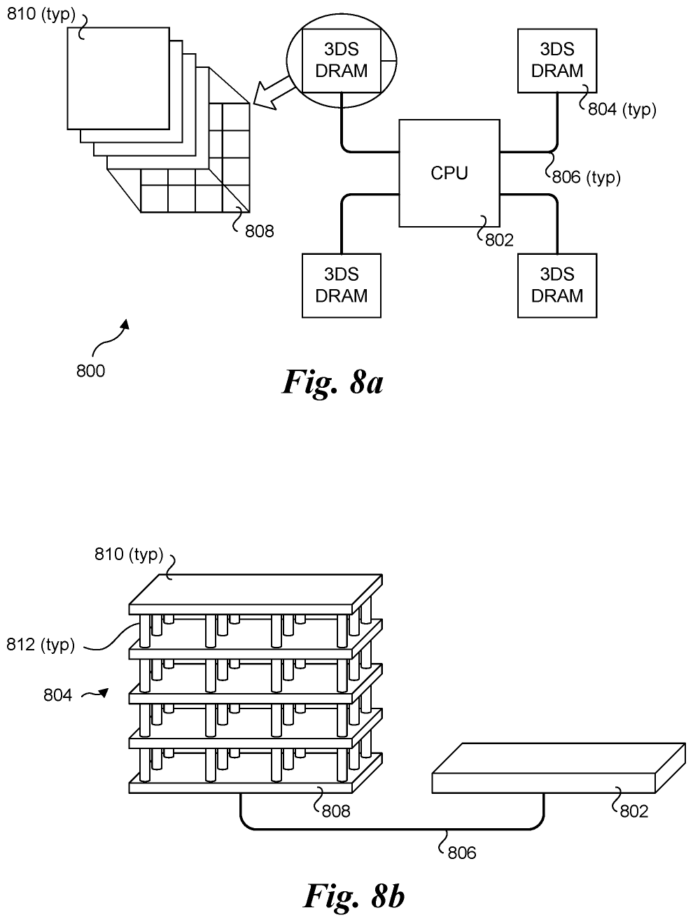

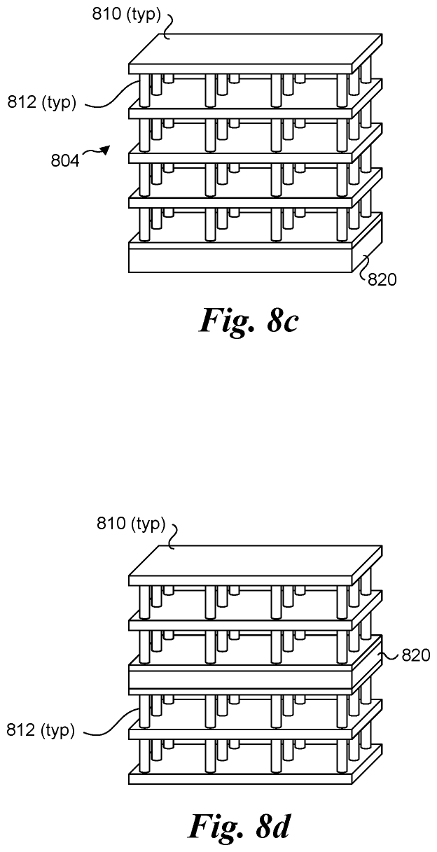

An example of a PIM module 800 is shown in FIGS. 8a and 8b. PIM module 800 includes a CPU 802 coupled to 3DS (three dimensional stacked) DRAMs 804 via respective memory channels 806, observing there may be multiple memory channels coupled between a CPU and a 3DS DRAM. As shown in the blow-up detail, a 3DS DRAM includes a logic layer comprising a logic die or compute die 808 above which multiple DRAM dies 810 are stacked. Logic die or compute die 808 and DRAM dies 810 are interconnected by TSVs 812.

An aspect of PIM modules is that the logic layer may perform compute operations that are separate from the compute operations performed by the CPU, hence comprise a compute die. In some instances, the logic layer comprises a processor die or the like. For example, system 400 may be implemented using a 3D stacked structure similar to that shown in FIG. 8b, where compute die 808 comprises an SoC with one or more compute elements (e.g., processor cores) and an integrated memory controller. In one embodiment, a portion of TSVs 812 is used for memory controller I/O interface interconnects for one or more memory channels. The number and density of the TSV is much greater than shown in FIG. 8b, which shows a simplified representation of the 3D stacked structure of an exemplary PIM.

FIGS. 8c and 8d show an example of a CPU or XPU (Other Processing Unit) 820 that is used in place of logic die or compute die 808 without a separate CPU. Under the embodiment shown in FIG. 8c, 3DS DRAMs 804 are above CPU/XPU 820. In the embodiment shown in FIG. 8d, one or more layers of DRAM dies 810 are above and below CPU/XPU 820.

In addition to systems with CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU or processor in the illustrated embodiments.

In addition to 3D stacked structures with TSVs, other types of packaging may be used, such as multichip modules and packages using die-to-die or chiplet-to-chiplet interconnect structures. For instance, in one embodiment memory channels 806 in FIGS. 8a and 8b are implemented using TSVs in a silicon die-to-die interconnect.

Under the embodiments described and illustrated above, sufficient wires per DRAM channel for full duplex operation are provided but do not increase the bank resources per channel. This provides opportunity for full duplex when there are available channel resources, such as when there is good DRAM page locality. The full duplex capability also eliminates the performance penalty of read-write turnarounds of traditional half duplex interfaces for DRAM. With tightly coupled compute die and DRAM die wires are low cost due to the high-density interconnect, e.g., with 25 um micro bumps and 9 um and smaller interconnect with hybrid bonding. A key metric to optimize in such scenarios is the bandwidth to DRAM area. The use of packages/structures with tightly coupled compute die and DRAM die wires/TSVs provide higher density interconnects while reducing interconnect costs. This also substantially enhances the bandwidth to DRAM area. The embodiments described and illustrated herein demonstrate schemes for enhancing the performance of existing bank resources per DRAM channel by providing more wires to facilitate concurrent read and write memory access.

### Experimental Performance Data

The following tables list performance data under different macro and bank configurations, but all for the case of banks sets matching bank groups. The CAS/ACT is the number of Column Activation Strobes per Activation. The 1:1, 2:1, and 3:1 parameters are (R)ead:(W)rite ratios. Under all the models, the tRRD_L=tCCD_L=2 ns. By way of example, the nomenclature 4bgx4 in TABLE 2 means there are 4 bank groups of 4 banks.

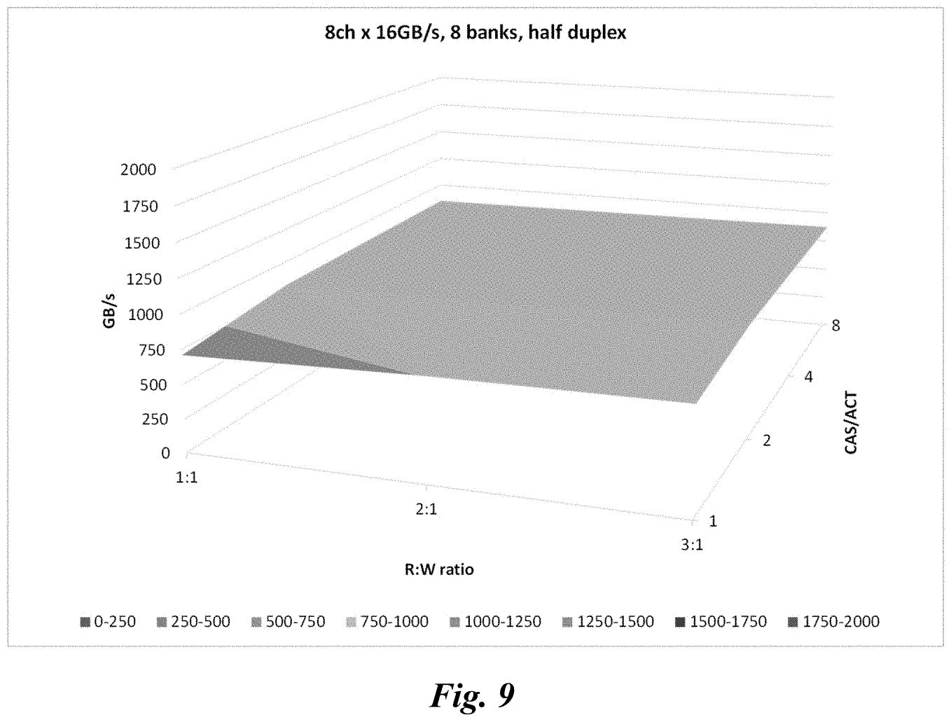

As a baseline for comparison, TABLE 1 and the chart in FIG. 9 shows the maximum bandwidth envelope for a memory system employing traditional half duplex channels with typical bank resources—8 banks per channel in this case—combined into 8 “macros” where each macro has 8 channels of 16 GB/s each. There are a total of 64 banks per macro.

TABLE 1
8 banks Half Duplex

| CAS/ACT | 1:1 | 2:1 | 3:1 |
|---|---|---|---|
| 1 | 708 | 752 | 766 |
| 2 | 817 | 837 | 854 |
| 4 | 835 | 851 | 865 |
| 8 | 851 | 862 | 874 |

As demonstrated by comparing the data in TABLE 2 and TABLE 3, increasing the number of bank groups for the same number of banks provides approximately 5% bandwidth increase for a 1:1 R/W ratio, with somewhat lesser performance as the R/W ratio is increased. For R:W ratios of 2:1 and 3:1 and CAS/ACT ratios of 4 and 8 the performance is substantially the same.

TABLE 2
16 banks 4bgx4 Full Duplex BankGroup

| CAS/ACT | 1:1 | 2:1 | 3:1 |
|---|---|---|---|
| 1 | 783 | 810 | 825 |
| 2 | 1160 | 1181 | 1165 |
| 4 | 1499 | 1403 | 1254 |
| 8 | 1708 | 1411 | 1256 |

TABLE 3
16 banks 8bgx2 Full Duplex BankGroup

| CAS/ACT | 1:1 | 2:1 | 3:1 |
|---|---|---|---|
| 1 | 818 | 853 | 870 |
| 2 | 1255 | 1274 | 1219 |
| 4 | 1628 | 1406 | 1253 |
| 8 | 1809 | 1410 | 1255 |

TABLES 4 and 5 show bandwidth data from 32 bank configurations of 8 bank groups of 4 banks (TABLE 4) and 16 bank groups of 2 banks (TABLE 5). Under these configurations, the largest bandwidth performance increase is observed for R/W ratios of 1:1 and 2:1 for CAS/ACT ratios of 1, and a R/W ratio of 1:1 for the CAS/ACT of 2. The remaining combinations result in similar bandwidth observations.

TABLE 4
32 banks 8bgx4 Full Duplex BankGroup

| CAS/ACT | 1:1 | 2:1 | 3:1 |
|---|---|---|---|
| 1 | 1290 | 1307 | 1246 |
| 2 | 1708 | 1419 | 1263 |
| 4 | 1880 | 1423 | 1262 |
| 8 | 1895 | 1422 | 1264 |

TABLE 5
32 banks 16bgx2 Full Duplex BankGroup

| CAS/ACT | 1:1 | 2:1 | 3:1 |
|---|---|---|---|
| 1 | 1350 | 1349 | 1251 |
| 2 | 1779 | 1417 | 1261 |
| 4 | 1897 | 1422 | 1259 |
| 8 | 1899 | 1420 | 1264 |

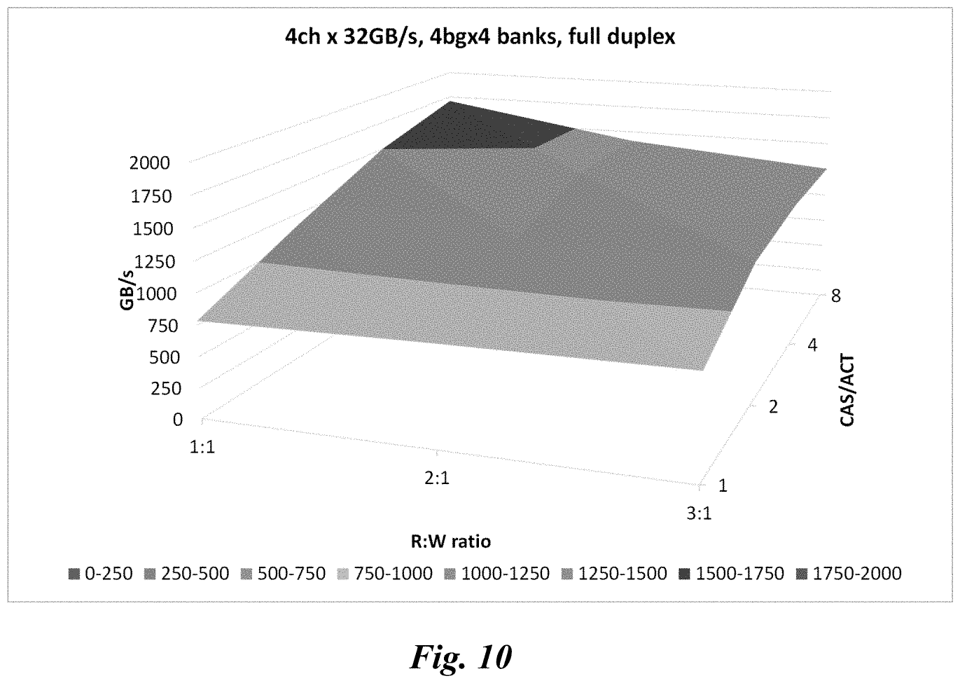

The chart in FIG. 10 shows the maximum bandwidth envelope for a memory system comprised of full duplex channels. Each “macro” now has four channels at 32 GB/s each direction and the total system still has 8 macros. To achieve this maximum concurrent bandwidth the DRAM requires (1) More banks: 32 banks/ch, for a total of 128 banks per macro; and (2) Tighter DRAM timing constraints for parameters such as tRRD and tFAW.

The benefit is a huge increase in bandwidth. But that bandwidth increase comes with a significant area increase due to a doubling of the total number of banks. This is not the best use of the resources: larger peak bandwidth can be achieved by splitting the full duplex channels into double the number of half duplex channels.

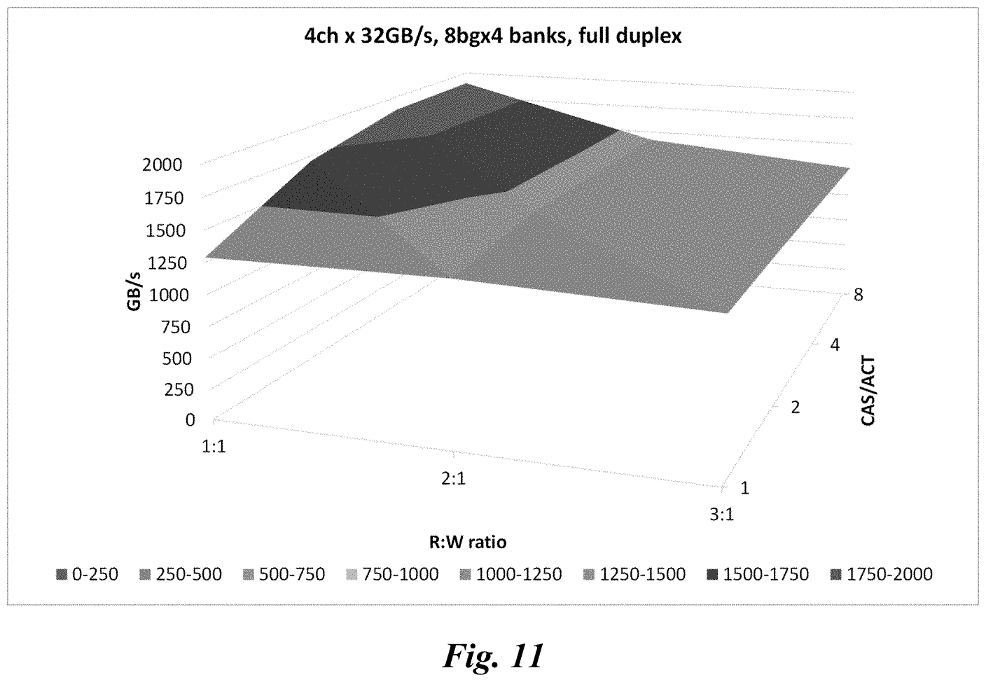

The chart in FIG. 11 shows the maximum bandwidth envelope for opportunistic full duplex. In this case the “macro” also has four channels with 32 GB/s each direction. However, this macro has 16 banks per channel, for a total of 64 banks per macro, the same as the half duplex baseline. The benefit is 20-100% (traffic dependent) increase in bandwidth with a small increase in the macro area.

### Example Compute Platform

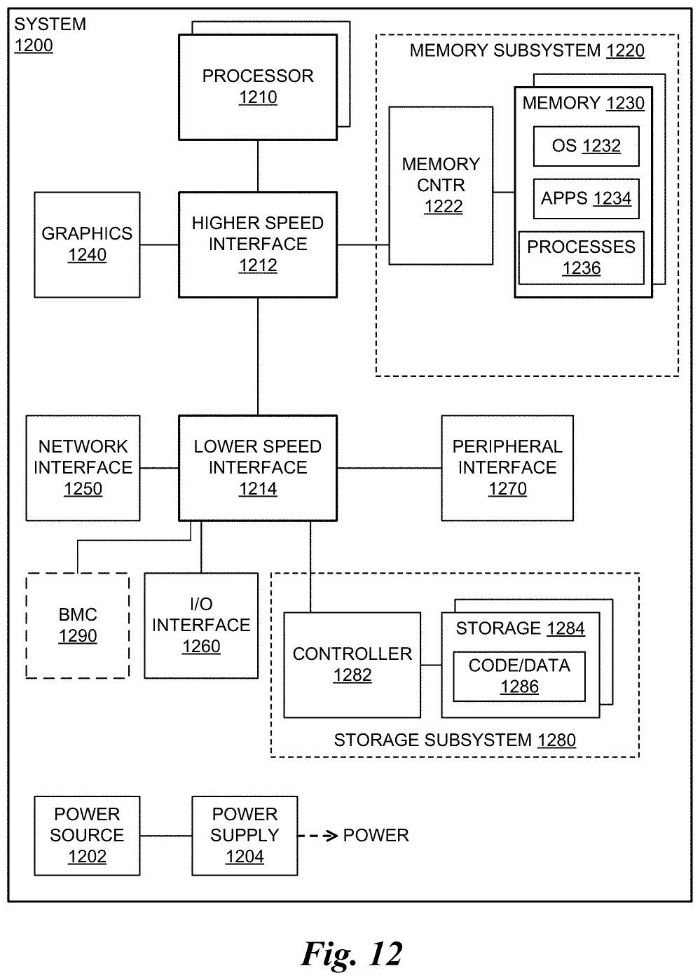

FIG. 12 illustrates an example compute platform 1200 in which aspects of the embodiments may be practiced. Compute platform 1200 represents a computing device or computing system in accordance with any example described herein, and can be a server, laptop computer, desktop computer, or the like. More generally, compute platform 1200 is representative of any type of computing device or system employing DRAM DIMMs.

Compute platform 1200 includes a processor 1210, which provides processing, operation management, and execution of instructions for compute platform 1200. Processor 1210 can include any type of microprocessor, central processing unit (CPU), graphics processing unit (GPU), processing core, or other processing hardware to provide processing for compute platform 1200, or a combination of processors. Processor 1210 controls the overall operation of compute platform 1200, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, compute platform 1200 includes interface 1212 coupled to processor 1210, which can represent a higher speed interface or a high throughput interface for system components that needs higher bandwidth connections, such as memory subsystem 1220 or graphics interface components 1240. Interface 1212 represents an interface circuit, which can be a standalone component or integrated onto a processor die. Where present, graphics interface 1240 interfaces to graphics components for providing a visual display to a user of compute platform 1200. In one example, graphics interface 1240 can drive a high definition (HD) display that provides an output to a user. High definition can refer to a display having a pixel density of approximately 100 PPI (pixels per inch) or greater and can include formats such as full HD (e.g., 1080 p), retina displays, 4K (ultra-high definition or UHD), or others. In one example, the display can include a touchscreen display. In one example, graphics interface 1240 generates a display based on data stored in memory 1230 or based on operations executed by processor 1210 or both.

Memory subsystem 1220 represents the main memory of compute platform 1200 and provides storage for code to be executed by processor 1210, or data values to be used in executing a routine. Memory 1230 of memory subsystem 1220 may include one or more memory devices such as DRAM DIMMs, read-only memory (ROM), flash memory, or other memory devices, or a combination of such devices. Memory 1230 stores and hosts, among other things, operating system (OS) 1232 to provide a software platform for execution of instructions in compute platform 1200. Additionally, applications 1234 can execute on the software platform of OS 1232 from memory 1230. Applications 1234 represent programs that have their own operational logic to perform execution of one or more functions. Processes 1236 represent agents or routines that provide auxiliary functions to OS 1232 or one or more applications 1234 or a combination. OS 1232, applications 1234, and processes 1236 provide software logic to provide functions for compute platform 1200. In one example, memory subsystem 1220 includes memory controller 1222, which is a memory controller to generate and issue commands to memory 1230. It will be understood that memory controller 1222 could be a physical part of processor 1210 or a physical part of interface 1212. For example, memory controller 1222 can be an integrated memory controller, integrated onto a circuit with processor 1210.

While not specifically illustrated, it will be understood that compute platform 1200 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one example, compute platform 1200 includes interface 1214, which can be coupled to interface 1212. Interface 1214 can be a lower speed interface than interface 1212. In one example, interface 1214 represents an interface circuit, which can include standalone components and integrated circuitry. In one example, multiple user interface components or peripheral components, or both, couple to interface 1214. Network interface 1250 provides compute platform 1200 the ability to communicate with remote devices (e.g., servers or other computing devices) over one or more networks. Network interface 1250 can include an Ethernet adapter, wireless interconnection components, cellular network interconnection components, USB (universal serial bus), or other wired or wireless standards-based or proprietary interfaces. Network interface 1250 can exchange data with a remote device, which can include sending data stored in memory or receiving data to be stored in memory.

In one example, compute platform 1200 includes one or more I/O interface(s) 1260. I/O interface(s) 1260 can include one or more interface components through which a user interacts with compute platform 1200 (e.g., audio, alphanumeric, tactile/touch, or other interfacing). Peripheral interface 1270 can include any hardware interface not specifically mentioned above. Peripherals refer generally to devices that connect dependently to compute platform 1200. A dependent connection is one where compute platform 1200 provides the software platform or hardware platform or both on which operation executes, and with which a user interacts.

In one example, compute platform 1200 includes storage subsystem 1280 to store data in a nonvolatile manner. In one example, in certain system implementations, at least certain components of storage subsystem 1280 can overlap with components of memory subsystem 1220. Storage subsystem 1280 includes storage device(s) 1284, which can be or include any conventional medium for storing large amounts of data in a nonvolatile manner, such as one or more magnetic, solid state, or optical based disks, or a combination. Storage device(s) 1284 holds code or instructions and data 1286 in a persistent state (i.e., the value is retained despite interruption of power to compute platform 1200). A portion of the code or instructions may comprise platform firmware that is executed on processor 1210. Storage device(s) 1284 can be generically considered to be a “memory,” although memory 1230 is typically the executing or operating memory to provide instructions to processor 1210. Whereas storage device(s) 1284 is nonvolatile, memory 1230 can include volatile memory (i.e., the value or state of the data is indeterminate if power is interrupted to compute platform 1200). In one example, storage subsystem 1280 includes controller 1282 to interface with storage device(s) 1284. In one example controller 1282 is a physical part of interface 1214 or processor 1210 or can include circuits or logic in both processor 1210 and interface 1214.

Compute platform 1200 may include an optional Baseboard Management Controller (BMC) 1290 that is configured to effect the operations and logic corresponding to the flowcharts disclosed herein. BMC 1290 may include a microcontroller or other type of processing element such as a processor core, engine or micro-engine, that is used to execute instructions to effect functionality performed by the BMC. Optionally, another management component (standalone or comprising embedded logic that is part of another component) may be used.

Power source 1202 provides power to the components of compute platform 1200. More specifically, power source 1202 typically interfaces to one or multiple power supplies 1204 in compute platform 1200 to provide power to the components of compute platform 1200. In one example, power supply 1204 includes an AC to DC (alternating current to direct current) adapter to plug into a wall outlet. Such AC power can be renewable energy (e.g., solar power) power source 1202. In one example, power source 1202 includes a DC power source, such as an external AC to DC converter. In one example, power source 1202 can include an internal battery or fuel cell source.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Various components and logic blocks may be implemented circuitry including but not limited to embedded hardware or the like, hardware modules, special-purpose hardware (e.g., application specific hardware, ASICs, DSPs, FPGAs, etc.), embedded controllers, hardwired circuitry, hardware logic, etc. Embedded logic may include processing elements that execute firmware and/or may employ microcode.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus comprising:
a memory controller including,
a memory channel interface, configured to be coupled to a mating memory channel interface on a memory device having a plurality of banks comprising multiple sets of banks, including,
a set of read data (RdDQ) lines;
a set of write data (WrDQ) lines;
one or more command signal lines; and
logic to implement full duplex concurrent read and write operations using commands sent over the one or more command signal lines and under which read data read from a first bank within a set of banks are received over the set of RdDQ lines while write data destined to be written to a second bank within a second set of banks are concurrently sent over the set of WrDQ lines.

2. The apparatus of claim 1, comprising multiple memory channel interfaces, each configured to interface with a respective memory device having a plurality of banks and including:
a respective set of RdDQ lines;
a respective set of WrDQ lines; and
the memory controller including logic to implement full duplex concurrent read and write operations under which read data stored in a first respective bank within a first respective set banks are received over a respective set of RdDQ lines while write data destined to be written to a second respective bank within a second respective set of banks are concurrently sent over a respective set of WrDQ lines.

3. The apparatus of claim 1, wherein the memory channel interface is coupled to one or more memory dies in a stacked three-dimensional (3D) structure.

4. The apparatus of claim 3, wherein the memory controller is implemented in a compute die in a stacked 3D structure including the compute die and one or more memory dies stacked above the compute die, wherein the compute die comprises a central processing unit (CPU) or other processing unit (XPU)

5. The apparatus of claim 1, wherein in the plurality of banks are partitioned into a plurality of bank groups, further configured to support concurrent read and write data transfers to respective banks within the same bank group of the memory device.

6. The apparatus of claim 1, further comprising a System on a Chip (SoC) in which the memory controller is implemented and including one or more compute elements coupled to the memory controller.

7. The memory controller of claim 1, wherein the memory controller is implemented in a die and the memory channel interface comprises a die-to-die interface.

8. The memory controller of claim 1, wherein the set of RdDQ lines and the set of WrDQ lines comprise through silicon vias (TSVs).

9. An apparatus comprising:
one or more memory devices having a plurality of banks comprising multiple sets of banks;
a memory controller, coupled to the one or more memory devices via plurality of memory channel interfaces, each including respective sets of Read data (RdDQ) lines and Write data (WrDQ) lines, one or more command signal lines and at least one clock signal line; and
logic to implement full duplex concurrent read and write operations using commands sent over the one or more command signal lines and under which read data stored in a first bank within a first set of banks in a memory device are received over the set of RdDQ lines for a memory channel interface while write data destined to be written to a second bank within a second set of banks in the memory device are concurrently sent over the set of WrDQ lines for the memory channel interface.

10. The apparatus of claim 9, further comprising a System on a Chip (SoC) in which the memory controller is implemented and including one or more compute elements coupled to the memory controller.

11. The apparatus of claim 10, wherein the apparatus comprises a stacked three-dimensional (3D) structure comprising an SoC die on which one or more memory dies are stacked, wherein are least one memory channel interface is coupled to at least one memory die using a set of through silicon vias (TSVs).

12. The apparatus of claim 10, wherein the SoC comprises an SoC die including the memory controller, the one or more memory devices comprises one or more memory dies, and wherein the SoC die is coupled to the one or more memory dies via one or more die-to-die interconnects.

13. The apparatus of claim 9, wherein, for each of at least one of the memory channel interfaces, a memory device coupled to the memory channel interface is configured to support concurrent read transfers from and write transfers to the same bank on the memory device.

14. The apparatus of claim 9, wherein, for each of at least one of the memory channel interfaces, a memory device coupled to the memory channel interface is configured to support concurrent read transfers from and write transfers to respective banks within the same set of banks.

15. The apparatus of claim 9, wherein a memory device comprises,
memory channel input-output (IO) interface circuitry including a set of RdDQ lines and a set of WrDQ lines, one or more command signal lines, and at least one clock signal line; and
a macro block of IO drivers coupled to the memory channel IO interface circuitry via a macro interface and coupled to at least a portion of the plurality of banks on the memory device, wherein the macro interface is configured to support full duplex operations under which read and write data are concurrently transferred over the macro interface.

16. A memory device, comprising:
a plurality of banks, each bank comprising an array of memory cells, the plurality of banks comprising multiple sets of banks;
one or more memory channel interfaces, each memory channel interface configured to be coupled to a mating memory channel interface on a memory controller and including respective sets of Read data (RdDQ) lines and Write data (WrDQ) lines, one or more command signal lines and at least one clock signal line; and
one or more sets of input-output (IO) drivers coupled between the one or more memory channel interfaces and respective groups or sets of banks among the plurality of banks,
wherein a memory channel interface is configured to support concurrent read and write data transfers by sending data read from in a first bank within a first set of banks over the set of RdDQ lines while concurrently receiving data over the set of WrDQ lines destined to be written to a second bank within a second set of banks.

17. The memory device of claim 16, wherein the one or more sets of IO drivers comprise a macro block of IO drivers, and wherein the macro block of IO drivers is coupled to one or more memory channel interfaces via one or more respective macro interfaces supporting full duplex operations under which read data and write data are concurrently sent over the macro interface.

18. The memory device of claim 17, wherein a portion of IO drivers in a macro block are connected to a bank and support full duplex operations under which independent read and write operations may be performed concurrently for the bank.

19. The memory device of claim 15, wherein respective portions of IO drivers in a macro block are connected to respective banks via respective pairs of uni-directional links, and the memory device supports concurrent full duplex operations using the pairs of uni-directional links under which read and write operations are performed concurrently for the respective banks.

20. The memory device of claim 15, comprising a plurality of memory channel interfaces coupled to respective macro blocks of IO drivers via respective macro interfaces.
